(19) United States
(12) Patent Application Publication
(10) Pub. No.: US 2024/0219452 A1
(43) Pub. Date: Jul. 4, 2024

(54) METHOD AND SYSTEM FOR A VACUUM COMPATIBLE ELECTRICAL INTERFACE, ENABLING MICROPROCESSOR DEBUG, AT HIGH SPEED, INSIDE AN ELECTRON BEAM PROBE

(71) Applicant: Intel Corporation, Santa Clara, CA (US)

(72) Inventors: Prasoon JOSHI, Hillsboro, OR (US); Joseph BASILE, Beaverton, OR (US); Eric BRUMMER, Orangevale, CA (US); Evan FLEDELL, Portland, OR (US); Joshua FREIER, Portland, OR (US); Brett GROSSMAN, Forest Grove, OR (US); Jennifer HUENING, Hillsboro, OR (US); Matthew KIRSCH, Hillsboro, OR (US); James NEEB, Gilbert, AZ (US); Robert NESTING, Forest Grove, OR (US); Charles PETERSON, Hillsboro, OR (US); Ashraf REZAIE, Portland, OR (US); Ling Hong TAN, Simpang Ampat (MY); Xianghong TONG, Hillsboro, OR (US); Vladimir VLASYUK, Folsom, CA (US)

(21) Appl. No.: 18/090,422

(22) Filed: Dec. 28, 2022

(51) Int. Cl. G01R 31/28; G01R 1/07

(52) U.S. Cl. CPC G01R 31/2834; G01R 1/071; G01R 31/2863

(57) ABSTRACT

The disclosure is directed to a device interface, system and method for connecting a Tester Interface Unit (TIU) to an automated test equipment that enable data rates of over 1.0 Gbps over scalable high speed cables. The device interface includes at least one flange assembly connecting an electron beam probe (EBP) in a vacuum-controlled environment to an ambient environment, the flange assembly including a vacuum-controlled passthrough environment coupled to the EBP, a plurality of cables coupled to a plurality of connectors within the vacuum-controlled passthrough environment to provide power, control and signal connections to the ambient environment, the plurality cables including plurality of hermetically-sealed printed circuit boards (PCBs) carrying digital high speed signals from the TIU, a plurality of power cables supporting a plurality of power requirements, and a plurality of ATE communication control cables to direct the TIU.

### TECHNICAL FIELD

This disclosure generally relates to field of microprocessor debugging, and more particularly relates to methods and apparatus for a vacuum-controlled environment compatible electrical interface that enables real-time probing of a microprocessor.

### BACKGROUND

Silicon debugging is a necessary part of determining why a microprocessor may or may not be working properly. Due to microprocessor dimensions shrinking and pattern density increasing, optical techniques are becoming inefficient in locating failures.

### BRIEF DESCRIPTION OF THE DRAWINGS

A detailed description is set forth below with reference to the accompanying drawings. The use of the same reference numerals may indicate similar or identical items. Various embodiments may utilize elements and/or components other than those illustrated in the drawings, and some elements and/or components may not be present in various embodiments. Elements and/or components in the figures are not necessarily drawn to scale. Throughout this disclosure, depending on the context, singular and plural terminology may be used interchangeably.

FIG. TA illustrates a microprocessor testing environment including flange assemblies in accordance with an embodiment of the disclosure.

FIG. 1B illustrates a close up of the testing environment including a flange assembly in accordance with an embodiment of the disclosure.

FIG. 2 illustrates an interface between an ATE in an ambient environment and an electron beam prober (EBP) in a vacuum-controlled environment in accordance with an embodiment of the disclosure.

FIG. 3A illustrates a plot of a 100 MHz waveform representative of circuit connections between an ATE and a Tester Interface Unit (TIU) in accordance with an embodiment of the disclosure.

FIG. 3B illustrates a plot of a 600 MHz waveform representative of circuit connections between an ATE and a (TIU) in accordance with an embodiment of the disclosure.

FIG. 4 illustrates a plot of pressure versus time within an electron beam probe (EBP) using the circuit connections between an ATE and a TIU in accordance with various embodiments of the disclosure.

FIG. 5 illustrates a flow diagram of a method in accordance with an embodiment of the disclosure.

### DETAILED DESCRIPTION

The following detailed description refers to the accompanying drawings. The same reference numbers may be used in different drawings to identify the same or similar elements. In the following description, for purposes of explanation and not limitation, specific details are set forth such as particular structures, architectures, interfaces, techniques, etc. in order to provide a thorough understanding of the various aspects of various embodiments. However, it will be apparent to those skilled in the art having the benefit of the present disclosure that the various aspects of the various embodiments may be practiced in other examples that depart from these specific details. In certain instances, descriptions of well-known devices, circuits, and methods are omitted so as not to obscure the description of the various embodiments with unnecessary detail. For the purposes of the present document, the phrases “A or B” and “A/B” mean (A), (B), or (A and B).

### Overview

In terms of a general overview, this disclosure is generally directed to systems and methods for a device interface and for connecting a Tester Interface Unit (TIU) to an automated test equipment (ATE) including at least one flange assembly connecting an electron beam probe (EBP) in a vacuum-controlled environment to an ambient environment, the flange assembly including a vacuum-controlled passthrough environment coupled to the EBP, a plurality of cables coupled to a plurality of connectors within the vacuum-controlled passthrough environment to provide power, control and signal connections to the ambient environment, the plurality cables including a plurality of hermetically-sealed printed circuit boards (PCBs) carrying digital high speed signals from the TIU, a plurality of power cables supporting a plurality of power requirements, and a plurality of ATE communication control cables to direct the TIU. In the present disclosure, a TIU may refer to a load board (or probe card): a printed circuit board for holding a device under test (DUT), and may apply to situations when a semiconductor package, die, or wafer is being probed.

Silicon debugging is a necessary part of determining why a microprocessor may or may not be working properly. One example of debugging occurs when conceptual electronic designs made into a taped version and then etched into a tangible silicon design are tested after fabrication. A debug laboratory may be used to determine why a silicon design is not working as expected once in silicon. When a microprocessor is not working as expected, after a tangible silicon design is available, often only a small region of a microprocessor may be failing. Due to microprocessor dimensions shrinking and pattern density increasing, optical techniques are becoming inefficient in locating failures.

Current microscopes include scanning electron microscopes (SEMs) that can view areas of a high density microprocessors. These SEMs may operate as electron beam probe (EBP) tools for testing purposes. Electron beam probing includes active voltage contrast and viewing of waveforms for debugging. However, these microscopes with EBP functionality require a vacuum-controlled environment. An automatic testing equipment (ATE) type tester applies an electrical stimulus to the microprocessor under test and the EBP looks at the response of the circuit elements to check the voltage response. However, electron microscopes used as a EBP tool need to be coupled to an ATE in an ambient environment. Connecting the EBP tool in a vacuum-controlled environment to an ATE controlled in an ambient environment is not currently supported for high density microprocessors. Accordingly, there is a need to enable EBP tools in a vacuum-controlled environment to connect with an ATE in an ambient environment for high density microprocessor debugging.

In one or more embodiments, the plurality of hermetically-sealed PCBs carrying digital high speed signals enable data rates of over 1.0 Gbps between the TIU and the ATE, and the digital high speed signals enable many (e.g., 904) input/output (IO) channels to support scalable connections between the vacuum-controlled environment and the ambient environment.

In one or more embodiments, the plurality of power cables include a plurality of PCBs capable of supporting fifty ATE power planes between the ATE and the TIU.

In one or more embodiments, the power cables include a plurality power options for powering the TIU including at least powers of 0.25 Amperes, 2 Amperes, and 24 Amperes, for example. Other power options may be implemented.

In one or more embodiments, the TIU is configured to hold a device under test (DUT), the TIU further coupled to a stage for receiving an electron beam from the EBP within the vacuum-controlled environment.

In one or more embodiments, the plurality of hermetically-sealed PCBs coupled to the TIU include up to eight flexible hermetically-sealed PCBs connected within the flange assembly, each of the eight flexible hermetically-sealed PCBs having up to 113 single-ended input/output (IO) channels.

In one or more embodiments, the plurality of hermetically-sealed PCBs coupled to the TIU have a length of between 14″ and 22″ from the flange assembly to the TIU to support movement of the TIU beneath an EBP electron beam.

In one or more embodiments, the flange assembly vacuum-controlled passthrough environment is hermetically sealed to enable a vacuum of at least 1e⁻⁷ Torr.

In one or more embodiments, the at least one flange assembly includes a plurality of weighted bars to support a connection area within the vacuum-controlled passthrough environment to enable engagement and disengagement of the connections to the flexible PCBs within the vacuum-controlled passthrough environment.

In one or more embodiments, the at least one flange assembly includes at least two flange assemblies, each flange assembly including a flange plate and a flange adapter, a first flange assembly includes the plurality of power cables and the plurality of ATE communication cables, a second flange assembly includes the plurality of hermetically sealed PCBs, and each of the at least two flange assemblies include a plurality of weight bearing pins on each respective flange plate to allow the flange assemblies to separate from each respective flange adapter to permit mating of the plurality of hermetically-sealed PCBs to connectors.

Another embodiment is directed to an automatic test equipment system for connecting to a vacuum-controlled environment of an electron beam probe (EBP), including an automatic test equipment (ATE) with a processor and a memory, a TIU for holding a device under test (DUT) within the EBP, the TIU and the EBP within the vacuum-controlled environment, at least one flange assembly connecting the vacuum-controlled environment to an ambient environment, the flange assembly including a vacuum-controlled passthrough environment coupled to an aperture of the EPB, a plurality of ATE cables coupled to the ATE, the plurality of ATE cables coupled to the vacuum-controlled passthrough environment via at least one hermetically sealed rigid printed circuit board (PCB) having a plurality of connectors operable to separate the ambient environment from the vacuum-controlled passthrough environment, and a plurality of hermetically-sealed flexible PCBs coupled to the plurality of connectors and coupled to the TIU to provide power, communication and digital high speed signaling.

In one or more embodiments of the automatic test equipment system, the plurality of hermetically-sealed flexible PCBs includes up to eight flexible hermetically-sealed PCBs connected within the flange assembly, each of the eight flexible hermetically-sealed PCBs with up to 113 single-ended input/output (IO) channels between the TIU and the ATE.

Another embodiment is direct to a method for an automatic test equipment system (ATE) connected to a tester in use (TIU) that is within a vacuum-controlled environment, the method including providing at least one flange assembly to connect the vacuum-controlled environment to an ambient environment for the ATE, the flange assembly including a vacuum-controlled passthrough environment coupled to an aperture of an electron beam probe (EBP), connecting a plurality of ATE cables to the ATE, the plurality of ATE cables coupled to the vacuum-controlled passthrough environment of the flange assembly via a plurality of hermetically sealed rigid printed circuit board (PCB) having a plurality of connectors operable to separate the ambient environment from the vacuum-controlled passthrough environment, and connecting the hermetically-sealed flexible PCBs to the plurality of connectors to transmit signals between the ambient environment and the vacuum-controlled environment.

In one embodiment, the method includes directing, by processing circuitry within the ATE, a probe of a device under test (DUT) connected to the TIU via the EBP stimulating a portion of the DUT, and receiving, in response, a plurality of the high speed digital signals via cables coupled to the TIU via a plurality of connectors within the vacuum-controlled passthrough environment.

Referring now to FIG. TA, in accordance with one or more embodiments, a device interface 100 connects a semiconductor device under test (DUT) 101 on a tester interface unit (TIU) 102 to automated test equipment (ATE) 106. Device interface 100 illustrates an embodiment appropriate for enabling an electron microscope operating as an electron beam probe 104 to connect to ATE 106. For example, ATE 106 include processing circuitry 180 including processor 190 coupled to memory 192 coupled to computerized machinery that uses test instruments such as TIU 102 to carry out and evaluate the results of functionality, performance, quality, and stress tests performed on electronic devices such as high density microprocessor with minimal human interaction.

The semiconductor device attributes are assessed by ATE 106, using processing circuitry 180, and for purposes of the present disclosure, DUT 101 shown on TIU 102 may be a highly dense processor or other logic/analog device (e.g., SRAM, etc.) being tested and requires testing to ensure adequate performance, functionality, and safety.

In accordance with one or more embodiments, device interface 100 includes at least one flange assembly coupled to a scanning electron microscope operable as an electron beam probe (EBP) 104. FIG. TA illustrates two flange assemblies, 108 and 110 coupled to EPB 104. As will be appreciated, system requirements regarding the footprint of any aperture or door of EPB 104 may dictate the number of flange assemblies. For purposes of the present disclosure, EPB 104 may include any EBP capable of examining a highly dense microprocessor capable of examination and testing by ATE 106 via a TIU, such as TIU 102. For example, some microprocessors appropriate for the present disclosure contain billions of transistors within a square centimeter.

In accordance with embodiments, each of flange assemblies 108 and 110 enable a plurality of cables to connect an ambient environment shown, including ATE cables 120 and 140 and pass through to a vacuum-controlled environment as flexible printed circuit boards (PCB) 122 within the respective flange assemblies. Thus, flange assemblies 108 and 110 create a vacuum-controlled passthrough environment 150 for connecting and disconnecting the plurality of cables. Other embodiments may have other configurations such as a single flange assembly or additional flange assemblies that accommodate a given EBP 104. As shown, both flange assemblies 108 and 110 may hold hermetically sealed PCBs, which may include both rigid and flexible PCBs. For example, each of flange assembly 108 and 110 may include respective flange plates 114 and flange adapters 116 to enable connection to a scanning electron microscope (SEM) operable as EBP 104. Each flange assembly 108 and 110 may include a flange plate 114 and flange adapter 116 that operate to create a vacuum-controlled passthrough environment wherein flexible PCBs 122 may connect to hermetically sealed rigid PCBs to enable connectors to pass through to an ambient environment where ATE 106 may send and receive power and signals to control TIU 102 and receive outputs from TIU 102 over high speed data connections. In one or more embodiments, the flange adapters 116 may be machined to allow mounting of each flange. Flange adapters 116 may be machined to allow for a vacuum-controlled passthrough environment 150 with PCBs, both flexible 122 and rigid to protrude from the vacuum-controlled passthrough environment 150 while allowing enough space to attach cables using connections such as very high density right angle connections and the like. A SEM electron column may offer a spatial resolution from 2 nm-20 nm, for example, but is not intended to be limiting. An EBP stage may have a load-bearing capability upwards of 1 kg, for example, but is not intended to be limiting.

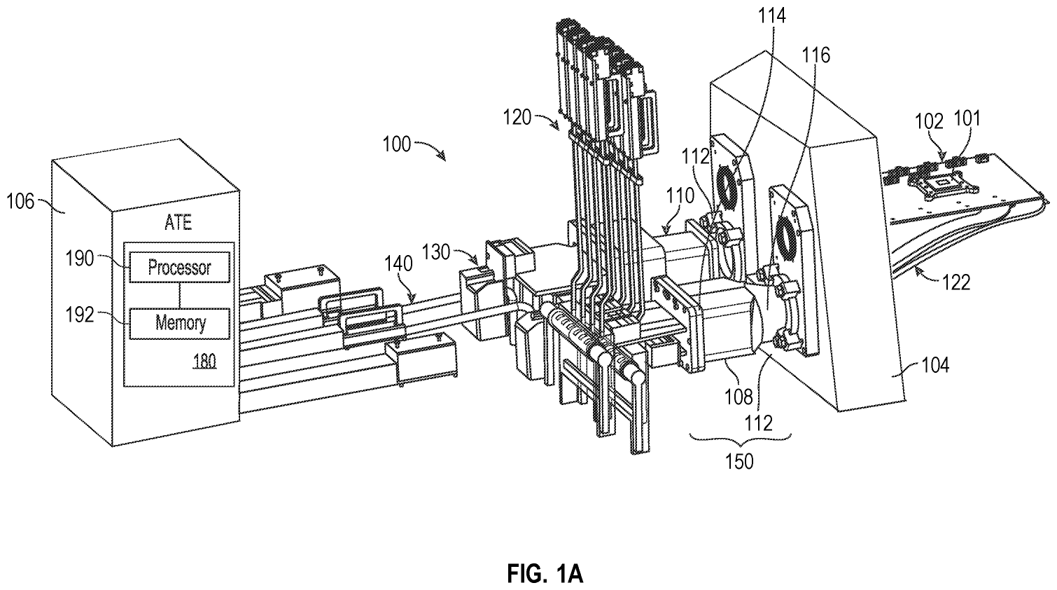

Referring to FIG. 1B, a blow up of an opened version of flange assembly 108 is illustrated to show more detail within flange assembly 108. As shown, flange assembly 108 may include weight bearing pins 170 designed onto a flange plate 114 to allow flange assembly 108 to be pulled back from a flange adapter 116 and mate/un-mate cables such as flexible PCBs 122 that may passthrough EBP 104 and through flange assembly 108. In one embodiment, a flange assembly 108 may include 0.65 mm right angle (RA) pitch connectors 109 to provide a compact area for digital input/output in a small area.

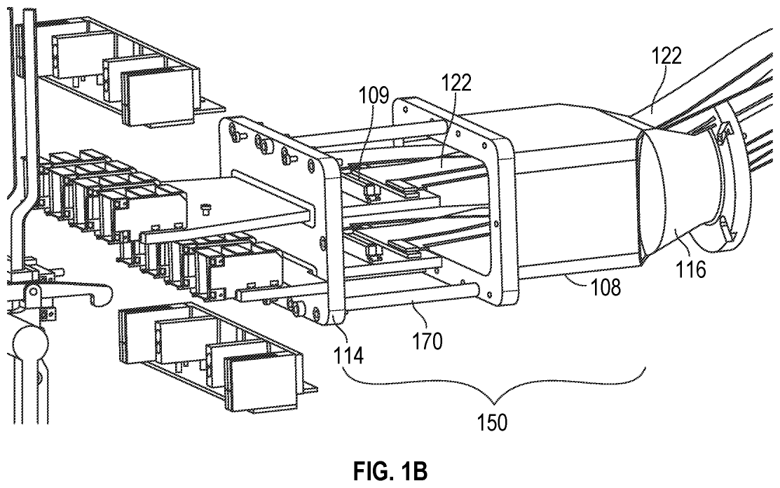

Referring to FIG. 2, an exemplary device interface 200 is shown that highlights a possible organization for either flange assembly 108 or 110. Specifically, as shown, TIU 102 may be attached to an SEM operable as an EBP 104 with a stage in a vacuum-controlled column where electron scanning may take place. FIG. 2 also illustrates rigid PCB 210 and includes connectors 212 to enable a separation between vacuum environment 230 and ambient environment 240. The different connectors 109 shown near flexible PCBs 122 enable rigid PCB 210 to receive up to 904 different IOs. In one embodiment, the 904 different IO connections may be made up of eight flexible hermetically-sealed PCBs 122 enabling 113 single-ended 50 Ohm channels.

As shown in flange assembly 108, high speed digital IO channels may be implemented with flexible PCBs 122 in a stripline design with a three-layer stack up commonly referred to in the art as ground-signal-ground (G-S-G) type layering. As will be appreciated, flexible PCBs, such as flexible PCBs 122 can be of many lengths to accommodate transfer through an SEM used as a EBP 104. For example, a length of flexible PCB is necessary to allow a feedthrough from flange assemblies 108 and 110 to TIU 102. Thus, the length of flexible PCBs 122 may be a function of the size of an EBP and also a function of the stage on which TIU 102 may be sitting. Further, different TIUs may be used and different-sized microprocessors may be under test with different electrical interface requirements. In one embodiment, for example, the flexible PCBs 122 may range from 14″ to 22″ in length and be 1.5″ in width with a 0.025″ thickness. Lengths may be chosen to provide enough service loop that will allow a particular DUT 101 to travel on a stage. In addition, lengths may be determined using a Time Domain Reflectometry (TDR) to insure no propagation delay or skew.

As will be appreciated by one of skill in the art, a movable stage for TIU 102 may require movement in many directions, such as x, y and z directions so that different areas of a DUT may be examined and tested. The flexible PCB 122 may also be stacked to accommodate different sized openings in and around an EBP 104 and to accommodate vacuum environmental needs. Thus, in one embodiment, flexible PCBs 122 within the vacuum-controlled environment may have low outgassing material, and withstand mild oxygen plasma. Thus, the plurality of IO connections enable scalability for different TIUs with different IO requirements.

In one embodiment, connectors 212 enable cables to connect with ATE cables such as typical coaxial cables in an ambient environment 240 that are appropriate for sending power and control signals to TIU 102 and for receiving high speed digital signals received after electrical stimulus is directed to an area under test on DUT 101 situated on TIU 102.

In another embodiment, cables in FIG. 2 may support a plurality of power planes from two Watts to 50 Watts of power through as many as 50 different power planes. For example, in one embodiment, flange assembly 110 may be organized to feed power, and also to provide ATE 106 to TIU 102 communications. To support structural integrity, on one embodiment rigid PCB 210 may be up to 14″ thick to enable trace length matching with board-to-board high density connectors 109 on the ambient side and high density, low profile, surface mount connectors within the vacuum-controlled environment.

As shown, flexible PCBs 122 from TIU 102 may be coupled to rigid PCB board-to-board connectors 109, which allow a PCB profile capable of being affixed and hermetically sealed with an epoxy through the flange plate 114. The connectors 109 may be chosen such that they support the needed electrical connections in a scalable manner.

The types of cables used for connecting TIU 102 to rigid flange PCBs as shown in FIGS. 1 and 2 may deliver power through, for example, 16 AWG cables, and, in one or more embodiments, custom shaped, outgassed cable. Outgassed cables as described herein includes cables are appropriate for vacuum-controlled environments to prevent cables from outgassing internal materials from the cable into the vacuum-controlled environment.

Further, flange assembly 110 may include ATE 106 to TIU 102 communication cables that may, in one embodiment, include 32 AWG cables that are vacuum environment compatible.

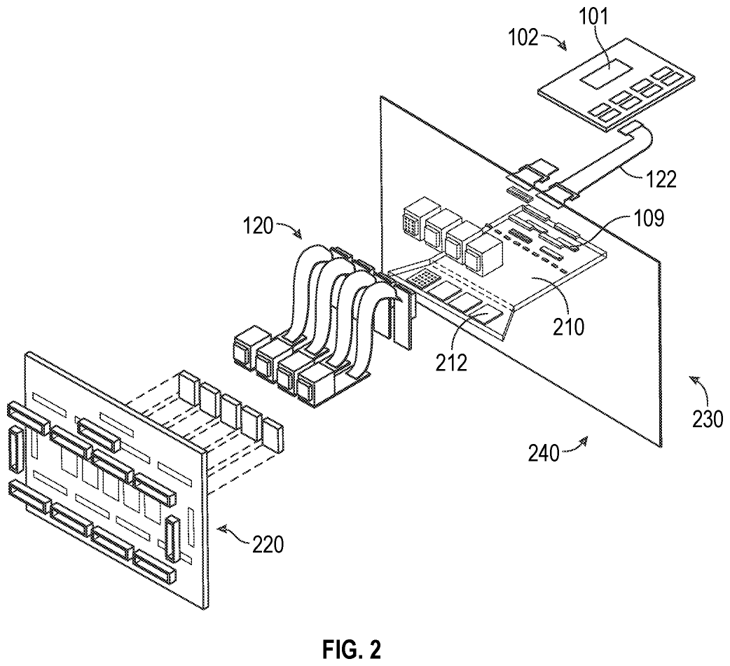

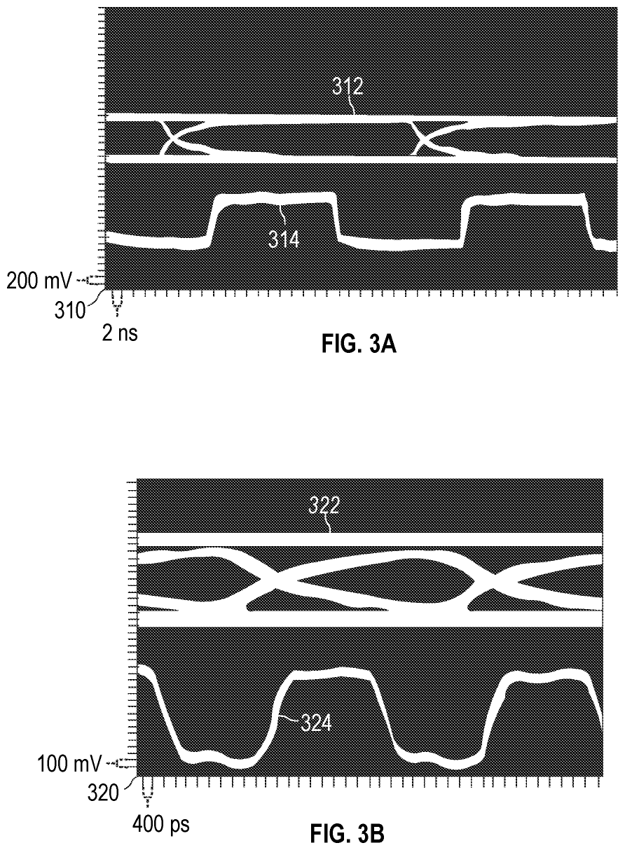

Referring now to FIGS. 3A and 3B, eye diagrams 310 and 320 illustrate measurements at operating frequencies of 100 MHz 310 and 600 MHz. As shown, flexible PCB 122 IO channels are represented by wave forms 312 and 322. Waveforms 314 and 324 represent reference square waves at the same frequencies. The eye waveforms illustrate that the interfaces connecting the vacuum-controlled environment to the ambient environment successfully provide interpretable readings for testing by ATE 106.

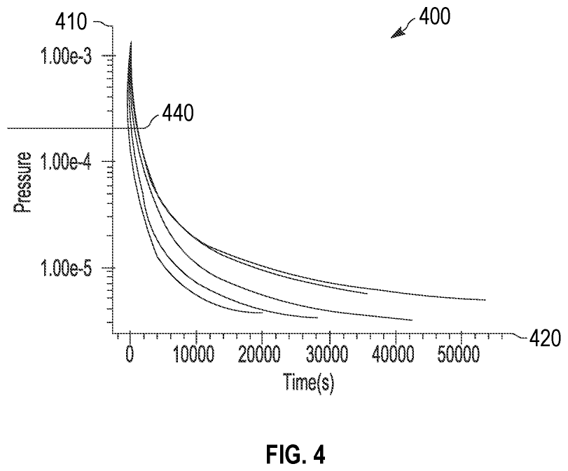

Referring to FIG. 4, a graph 400 illustrates pressure 410 representing a vacuum versus a time 420 for an automatic test equipment (ATE) 106 system using the device interface for connecting TIU 102 to ATE 106 using a flange assembly as described herein. As shown, the EBP 104 vacuum threshold 440 is achieved.

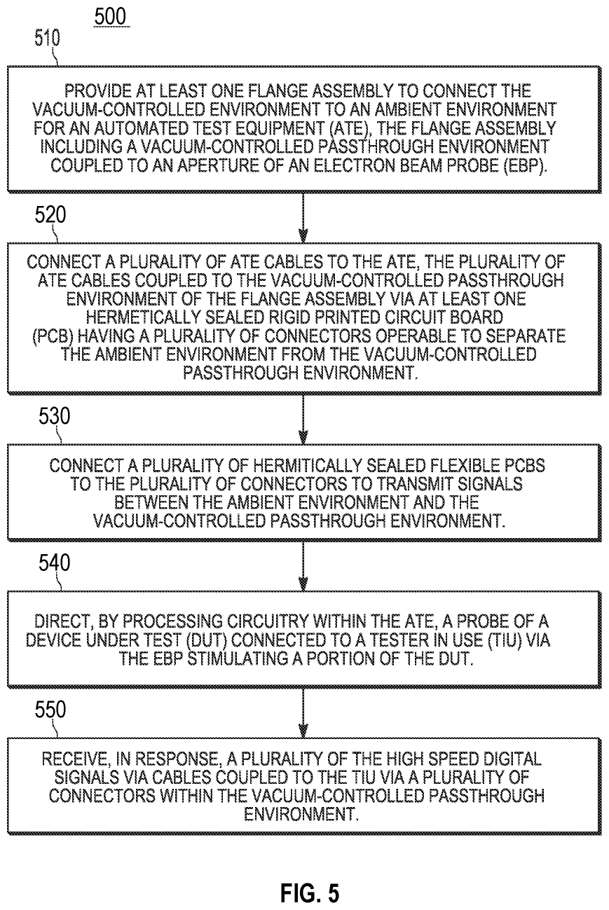

Referring now to FIG. 5, a flow diagram illustrates a method for an automatic test equipment system (ATE), such as ATE 106 connected to a tester in use (TIU), such as TIU 102 within a vacuum-controlled environment 230 in accordance with one or more embodiments.

Block 510 provides for providing at least one flange assembly to connect the vacuum-controlled environment to an ambient environment for an automated test equipment (ATE), the flange assembly including a vacuum-controlled passthrough environment coupled to an aperture of an electron beam probe (EBP). For example, flange assemblies 108 and 110 shown in FIG. TA connect vacuum-controlled environment 230 to ambient environment 240 where ATE 106 can provide control instructions. As shown in FIG. TA, flange assemblies 108 and 110 create a vacuum-controlled passthrough environment 150 when coupled to apertures 112 of EBP 104.

Block 520 provides for connecting a plurality of ATE cables to the ATE, the plurality of ATE cables coupled to the vacuum-controlled passthrough environment of the flange assembly via at least one hermetically sealed rigid printed circuit board (PCB) having a plurality of connectors operable to separate the ambient environment from the vacuum-controlled passthrough environment. For example, ATE 106 with ATE cables 140 and 120 coupled to ATE 106 wherein cables 140 and 120 are coupled through a flange assembly such as 108 and 110 via hermetically sealed rigid PCB 210 having connectors 109 to separate ambient environment 240 from vacuum-controlled passthrough environment 230.

Block 530 provides for connecting a plurality of hermetically-sealed flexible PCBs to the plurality of connectors to transmit signals between the ambient environment and the vacuum-controlled passthrough environment. For example, hermetically-sealed flexible PCBs 122 connect to connectors 109 transmit signals from TIU 102 to ATE 106 between vacuum-controlled passthrough environment 150 shown in FIG. TA to an ambient environment.

Block 540 provides for directing, by processing circuitry within the ATE, a probe of a device under test (DUT) connected to the TIU via the EBP stimulating a portion of the DUT. For example, processing circuitry 180 within ATE 106 may direct a probe using EBP 104 and TIU 102 holding DUT 101 to stimulate a portion of DUT 101.

Block 550 provides for receiving, in response, a plurality of the high speed digital signals via cables coupled to the TIU via a plurality of connectors within the vacuum-controlled passthrough environment. For example, ATE 106 receives a plurality of high speed digital signals via the hermetically-sealed flexible PCBs 122 coupled to TIU 102 via connectors 109 within vacuum-controlled passthrough environment 150. In one embodiment the ATE cables carry scalable high speed digital signals with data rates of over 1.0 Gbps between the TIU and the ATE through 904 input/output (IO) channels to support scalable connections.

In the above disclosure, reference has been made to the accompanying drawings, which form a part hereof, which illustrate specific implementations in which the present disclosure may be practiced. It is understood that other implementations may be utilized, and structural changes may be made without departing from the scope of the present disclosure. References in the specification to “one embodiment,” “an embodiment,” “an example embodiment,” “an example embodiment,” “example implementation,” etc., indicate that the embodiment or implementation described may include a particular feature, structure, or characteristic, but every embodiment or implementation may not necessarily include the particular feature, structure, or characteristic. Moreover, such phrases are not necessarily referring to the same embodiment or implementation. Further, when a particular feature, structure, or characteristic is described in connection with an embodiment or implementation, one skilled in the art will recognize such feature, structure, or characteristic in connection with other embodiments or implementations whether or not explicitly described. For example, various features, aspects, and actions described above with respect to an autonomous parking maneuver are applicable to various other autonomous maneuvers and must be interpreted accordingly.

Implementations of the systems, apparatuses, devices, and methods disclosed herein may comprise or utilize one or more devices that include hardware, such as, for example, one or more processors and system memory, as discussed herein. An implementation of the devices, systems, and methods disclosed herein may communicate over a computer network. A “network” is defined as one or more data links that enable the transport of electronic data between computer systems and/or modules and/or other electronic devices. When information is transferred or provided over a network or another communications connection (either hardwired, wireless, or any combination of hardwired or wireless) to a computer, the computer properly views the connection as a transmission medium. Transmission media can include a network and/or data links, which can be used to carry desired program code means in the form of computer-executable instructions or data structures and which can be accessed by a general purpose or special purpose computer. Combinations of the above should also be included within the scope of non-transitory computer-readable media.

A memory device can include any one memory element or a combination of volatile memory elements (e.g., random access memory (RAM, such as DRAM, SRAM, SDRAM, etc.)) and non-volatile memory elements (e.g., ROM, hard drive, tape, CDROM, etc.). Moreover, the memory device may incorporate electronic, magnetic, optical, and/or other types of storage media. In the context of this document, a “non-transitory computer-readable medium” can be, for example but not limited to, an electronic, magnetic, optical, electromagnetic, infrared, or semiconductor system, apparatus, or device. More specific examples (a non-exhaustive list) of the computer-readable medium would include the following: a portable computer diskette (magnetic), a random-access memory (RAM) (electronic), a read-only memory (ROM) (electronic), an erasable programmable read-only memory (EPROM, EEPROM, or Flash memory) (electronic), and a portable compact disc read-only memory (CD ROM) (optical). Note that the computer-readable medium could even be paper or another suitable medium upon which the program is printed, since the program can be electronically captured, for instance, via optical scanning of the paper or other medium, then compiled, interpreted or otherwise processed in a suitable manner if necessary, and then stored in a computer memory.

Those skilled in the art will appreciate that the present disclosure may be practiced in network computing environments with many types of computer system configurations, including in-dash vehicle computers, personal computers, desktop computers, laptop computers, message processors, nomadic devices, multi-processor systems, microprocessor-based or programmable consumer electronics, network PCs, minicomputers, mainframe computers, mobile telephones, PDAs, tablets, pagers, routers, switches, various storage devices, and the like. The disclosure may also be practiced in distributed system environments where local and remote computer systems, which are linked (either by hardwired data links, wireless data links, or by any combination of hardwired and wireless data links) through a network, both perform tasks. In a distributed system environment, program modules may be located in both the local and remote memory storage devices.

Further, where appropriate, the functions described herein can be performed in one or more of hardware, software, firmware, digital components, or analog components. For example, one or more application specific integrated circuits (ASICs) can be programmed to carry out one or more of the systems and procedures described herein. Certain terms are used throughout the description, and claims refer to particular system components. As one skilled in the art will appreciate, components may be referred to by different names. This document does not intend to distinguish between components that differ in name, but not function.

At least some embodiments of the present disclosure have been directed to computer program products comprising such logic (e.g., in the form of software) stored on any computer-usable medium. Such software, when executed in one or more data processing devices, causes a device to operate as described herein.

While various embodiments of the present disclosure have been described above, it should be understood that they have been presented by way of example only, and not limitation. It will be apparent to persons skilled in the relevant art that various changes in form and detail can be made therein without departing from the spirit and scope of the present disclosure. Thus, the breadth and scope of the present disclosure should not be limited by any of the above-described example embodiments but should be defined only in accordance with the following claims and their equivalents. The foregoing description has been presented for the purposes of illustration and description. It is not intended to be exhaustive or to limit the present disclosure to the precise form disclosed. Many modifications and variations are possible in light of the above teaching. Further, it should be noted that any or all of the aforementioned alternate implementations may be used in any combination desired to form additional hybrid implementations of the present disclosure. For example, any of the functionality described with respect to a particular device or component may be performed by another device or component. Further, while specific device characteristics have been described, embodiments of the disclosure may relate to numerous other device characteristics. Further, although embodiments have been described in language specific to structural features and/or methodological acts, it is to be understood that the disclosure is not necessarily limited to the specific features or acts described. Rather, the specific features and acts are disclosed as illustrative forms of implementing the embodiments. Conditional language, such as, among others, “can,” “could,” “might,” or “may,” unless specifically stated otherwise, or otherwise understood within the context as used, is generally intended to convey that certain embodiments could include, while other embodiments may not include, certain features, elements, and/or steps. Thus, such conditional language is not generally intended to imply that features, elements, and/or steps are in any way required for one or more embodiments.

### Terminology

For the purposes of the present document, the following terms and definitions are applicable to the examples and embodiments discussed herein.

The term “circuitry” as used herein refers to, is part of, or includes hardware components such as an electronic circuit, a logic circuit, a processor (shared, dedicated, or group) and/or memory (shared, dedicated, or group), an Application Specific Integrated Circuit (ASIC), a field-programmable device (FPD) (e.g., a field-programmable gate array (FPGA), a programmable logic device (PLD), a complex PLD (CPLD), a high-capacity PLD (HCPLD), a structured ASIC, or a programmable SoC), digital signal processors (DSPs), etc., that are configured to provide the described functionality. In some embodiments, the circuitry may execute one or more software or firmware programs to provide at least some of the described functionality. The term “circuitry” may also refer to a combination of one or more hardware elements (or a combination of circuits used in an electrical or electronic system) with the program code used to carry out the functionality of that program code. In these embodiments, the combination of hardware elements and program code may be referred to as a particular type of circuitry.

The term “processor circuitry” as used herein refers to, is part of, or includes circuitry capable of sequentially and automatically carrying out a sequence of arithmetic or logical operations, or recording, storing, and/or transferring digital data. Processing circuitry may include one or more processing cores to execute instructions and one or more memory structures to store program and data information. The term “processor circuitry” may refer to one or more application processors, one or more baseband processors, a physical central processing unit (CPU), a single-core processor, a dual-core processor, a triple-core processor, a quad-core processor, and/or any other device capable of executing or otherwise operating computer-executable instructions, such as program code, software modules, and/or functional processes. Processing circuitry may include more hardware accelerators, which may be microprocessors, programmable processing devices, or the like. The one or more hardware accelerators may include, for example, computer vision (CV) and/or deep learning (DL) accelerators. The terms “application circuitry” and/or “baseband circuitry” may be considered synonymous to, and may be referred to as, “processor circuitry.”

The term “interface circuitry” as used herein refers to, is part of, or includes circuitry that enables the exchange of information between two or more components or devices. The term “interface circuitry” may refer to one or more hardware interfaces, for example, buses, I/O interfaces, peripheral component interfaces, network interface cards, and/or the like.

The term “computer system” as used herein refers to any type interconnected electronic devices, computer devices, or components thereof. Additionally, the term “computer system” and/or “system” may refer to various components of a computer that are communicatively coupled with one another. Furthermore, the term “computer system” and/or “system” may refer to multiple computer devices and/or multiple computing systems that are communicatively coupled with one another and configured to share computing and/or networking resources.

The term “appliance,” “computer appliance,” or the like, as used herein refers to a computer device or computer system with program code (e.g., software or firmware) that is specifically designed to provide a specific computing resource. A “virtual appliance” is a virtual machine image to be implemented by a hypervisor-equipped device that virtualizes or emulates a computer appliance or otherwise is dedicated to provide a specific computing resource.

The terms “coupled,” “communicatively coupled,” along with derivatives thereof are used herein. The term “coupled” may mean two or more elements are in direct physical or electrical contact with one another, may mean that two or more elements indirectly contact each other but still cooperate or interact with each other, and/or may mean that one or more other elements are coupled or connected between the elements that are said to be coupled with each other. The term “directly coupled” may mean that two or more elements are in direct contact with one another. The term “communicatively coupled” may mean that two or more elements may be in contact with one another by a means of communication including through a wire or other interconnect connection, through a wireless communication channel or link, and/or the like.

Various example embodiments are provided below.

Example 1 may include a device interface for connecting a Tester Interface Unit (TIU) to an automated test equipment (ATE), the device interface comprising: at least one flange assembly connecting an electron beam probe (EBP) in a vacuum-controlled environment to an ambient environment, the flange assembly including a vacuum-controlled passthrough environment coupled to the EBP; and a plurality of cables coupled to a plurality of connectors within the vacuum-controlled passthrough environment to provide power, control and signal connections to the ambient environment, the plurality of cables including: a plurality of hermetically-sealed printed circuit boards (PCBs) carrying digital high speed signals from the TIU; a plurality of power cables supporting a plurality of power requirements; and a plurality of ATE communication control cables to direct the TIU.

Example 2 may include the device interface of example 1 and/or any other example herein, wherein the plurality of hermetically-sealed PCBs carrying digital high speed signals are configured to enable data rates of over 1.0 Gbps between the TIU and the ATE.

Example 3 may include the device interface of example 2 and/or any other example herein, wherein at least 900 input/output (IO) channels associated with the digital high speed signals are configured to support scalable connections between the ambient environment and the vacuum-controlled environment.

Example 4 may include the device interface of example 1 and/or any other example herein, wherein the plurality of power cables include a plurality of PCBs carrying at least fifty ATE power planes between the ATE and the TIU.

Example 5 may include the device interface of example 4 and/or any other example herein, wherein the power cables include a plurality power options for enabling exchanging the TIU including at powers of least 0.25 amperes, 2.0 amperes, and 24.0 amperes.

Example 6 may include the device interface of example 1 and/or any other example herein, wherein the TIU is configured to hold a device under test (DUT), the TIU further coupled to a stage for receiving an electron beam.

Example 7 may include the device interface of example 1 and/or any other example herein, wherein the plurality of hermetically-sealed PCBs coupled to the TIU comprises eight flexible hermetically-sealed PCBs connected within the flange assembly, each of the eight flexible hermetically-sealed PCBs comprising 113 single-ended 50 Ohm input/output (IO) channels.

Example 8 may include the device interface of example 1 and/or any other example herein, wherein the plurality of hermetically-sealed PCBs coupled to the TIU have a length of between 14 inches and 22 inches from the flange assembly to the TIU.

Example 9 may include the device interface of example 1 and/or any other example herein, wherein the vacuum-controlled passthrough environment is hermetically sealed to enable a vacuum of at least 1e-7 Torr.

Example 10 may include the device interface of example 1 and/or any other example herein, wherein the at least one flange assembly further comprises: a plurality of weighted bars to support a connection area within the vacuum-controlled passthrough environment configured to enable engagement and disengagement of the connections within the vacuum-controlled passthrough environment.

Example 11 may include the device interface of example 1 and/or any other example herein, wherein the at least one flange assembly comprises: at least two flange assemblies, each flange assembly comprising a flange plate and a flange adapter, wherein: a first flange assembly comprises the plurality of power cables and the plurality of ATE communication cables; and a second flange assembly comprises the plurality of hermetically sealed PCBs; and each of the at least two flange assemblies comprise a plurality of weight bearing pins on each respective flange plate to allow the flange assemblies to separate from each respective flange adapter to permit mating of the plurality of hermetically-sealed PCBs to connectors.

Example 12 may include an automatic test equipment system for an electron beam probe (EBP), the automatic test equipment system comprising: an automatic test equipment (ATE) including a processor and a memory; a tester in use (TIU) for holding a device under test (DUT) within the EBP, the TIU and the EBP within a vacuum-controlled environment; at least one flange assembly connecting the vacuum-controlled environment to an ambient environment including an automatic test equipment (ATE), the flange assembly including a vacuum-controlled passthrough environment coupled to an aperture of the EBP; a plurality of ATE cables coupled to the ATE, the plurality of ATE cables coupled to the vacuum-controlled passthrough environment via at least one hermetically sealed rigid printed circuit board (PCB) having a plurality of connectors operable to separate the ambient environment from the vacuum-controlled passthrough environment; and a plurality of hermetically-sealed flexible PCBs coupled to the plurality of connectors and coupled to the TIU to provide power, communication and digital high speed signaling.

Example 13 may include the automatic test equipment system of example 12 and/or any other example herein, wherein the plurality of hermetically-sealed flexible PCBs are configured to carry digital high speed signals enabling data rates of over 1.0 Gbps between the TIU and the ATE through at least 900 input/output (IO) channels to support scalable connections.

Example 14 may include the automatic test equipment system of example 12 and/or any other example herein, wherein the hermetically-sealed flexible PCBs comprise a plurality of power cables carrying fifty ATE power planes between the ATE and the TIU.

Example 15 may include the automatic test equipment system of example 12 and/or any other example herein, wherein the plurality of hermetically-sealed flexible PCBs comprise eight flexible hermetically-sealed PCBs connected within the flange assembly, each of the eight flexible hermetically-sealed PCBs comprising 113 single-ended input/output (IO) channels between the TIU and the ATE.

Example 16 may include the automatic test equipment system of example 12 and/or any other example herein, wherein the vacuum-controlled passthrough environment is hermetically sealed to enable a vacuum of at least 1e-7 Torr.

Example 17 may include the automatic test equipment system of example 12 and/or any other example herein, wherein the at least one flange assembly further comprises: at least two flange assemblies, the at least two flange assemblies including: a first flange assembly connecting a plurality of power cables and a plurality of ATE communication cables to the TIU via the aperture to the EBP; and a second flange assembly comprising configurable hermetically sealed flexible PCBs to provide the digital high speed signaling, wherein each of the at least two flange assemblies comprise a plurality of weight bearing pins to allow the respective flange assemblies to permit mating of a plurality of hermetically-sealed PCBs to a plurality of connectors within the vacuum-controlled passthrough environment.

Example 18 may include a method for an automatic test equipment system (ATE) connected to a tester in use (TIU) within a vacuum-controlled environment, the method comprising: providing at least one flange assembly to connect the vacuum-controlled environment to an ambient environment for the ATE, the flange assembly including a vacuum-controlled passthrough environment coupled to an aperture of an electron beam probe (EBP); connecting a plurality of ATE cables to the ATE, the plurality of ATE cables coupled to the vacuum-controlled passthrough environment of the flange assembly via at least one hermetically sealed rigid printed circuit board (PCB) having a plurality of connectors operable to separate the ambient environment from the vacuum-controlled passthrough environment; and connecting a plurality of hermetically-sealed flexible PCBs to the plurality of connectors to transmit signals between the ambient environment and the vacuum-controlled passthrough environment.

Example 19 may include the method of example 18 and/or any other example herein, further comprising: directing, by processing circuitry within the ATE, a probe of a device under test (DUT) connected to the TIU via the EBP stimulating a portion of the DUT; and receiving, in response, a plurality of high speed digital signals via cables coupled to the TIU via a plurality of connectors within the vacuum-controlled passthrough environment.

Example 20 may include the method of claim 19, wherein the ATE cables carry scalable high speed digital signals with data rates of over 1.0 Gbps between the TIU and the ATE through 904 input/output (IO) channels to support scalable connections.

That which is claimed is:

1. A device interface for connecting a Tester Interface Unit (TIU) to an automated test equipment (ATE), the device interface comprising:
at least one flange assembly connecting an electron beam probe (EBP) in a vacuum-controlled environment to an ambient environment, the flange assembly including a vacuum-controlled passthrough environment coupled to the EBP; and
a plurality of cables coupled to a plurality of connectors within the vacuum-controlled passthrough environment to provide power, control and signal connections to the ambient environment, the plurality of cables including:
a plurality of hermetically-sealed printed circuit boards (PCBs) carrying digital high speed signals from the TIU;
a plurality of power cables supporting a plurality of power requirements; and
a plurality of ATE communication control cables to direct the TIU.

2. The device interface of claim 1 wherein the plurality of hermetically-sealed PCBs carrying digital high speed signals are configured to enable data rates of over 1.0 Gbps between the TIU and the ATE.

3. The device interface of claim 2 wherein at least 900 input/output (IO) channels associated with the digital high speed signals are configured to support scalable connections between the ambient environment and the vacuum-controlled environment.

4. The device interface of claim 1, wherein the plurality of power cables include a plurality of PCBs carrying at least fifty ATE power planes between the ATE and the TIU.

5. The device interface of claim 4, wherein the power cables include a plurality power options for enabling exchanging the TIU including at powers of least 0.25 amperes, 2.0 amperes, and 24.0 amperes.

6. The device interface of claim 1, wherein the TIU is configured to hold a device under test (DUT), the TIU further coupled to a stage for receiving an electron beam.

7. The device interface of claim 1, wherein the plurality of hermetically-sealed PCBs coupled to the TIU comprises eight flexible hermetically-sealed PCBs connected within the flange assembly, each of the eight flexible hermetically-sealed PCBs comprising 113 single-ended 50 Ohm input/output (IO) channels.

8. The device interface of claim 1, wherein the plurality of hermetically-sealed PCBs coupled to the TIU have a length of between 14 inches and 22 inches from the flange assembly to the TIU.

9. The device interface of claim 1, wherein the vacuum-controlled passthrough environment is hermetically sealed to enable a vacuum of at least 1e⁻⁷ Torr.

10. The device interface of claim 1, wherein the at least one flange assembly further comprises:
a plurality of weighted bars to support a connection area within the vacuum-controlled passthrough environment configured to enable engagement and disengagement of the connections within the vacuum-controlled passthrough environment.

11. The device interface of claim 1, wherein the at least one flange assembly comprises:
at least two flange assemblies, each flange assembly comprising a flange plate and a flange adapter, wherein:
a first flange assembly comprises the plurality of power cables and the plurality of ATE communication cables; and
a second flange assembly comprises the plurality of hermetically sealed PCBs; and
each of the at least two flange assemblies comprise a plurality of weight bearing pins on each respective flange plate to allow the flange assemblies to separate from each respective flange adapter to permit mating of the plurality of hermetically-sealed PCBs to connectors.

12. An automatic test equipment system for an electron beam probe (EBP), the automatic test equipment system comprising:
an automatic test equipment (ATE) including a processor and a memory;
a tester in use (TIU) for holding a device under test (DUT) within the EBP, the TIU and the EBP within a vacuum-controlled environment;
at least one flange assembly connecting the vacuum-controlled environment to an ambient environment including an automatic test equipment (ATE), the flange assembly including a vacuum-controlled passthrough environment coupled to an aperture of the EBP;
a plurality of ATE cables coupled to the ATE, the plurality of ATE cables coupled to the vacuum-controlled passthrough environment via at least one hermetically sealed rigid printed circuit board (PCB) having a plurality of connectors operable to separate the ambient environment from the vacuum-controlled passthrough environment; and
a plurality of hermetically-sealed flexible PCBs coupled to the plurality of connectors and coupled to the TIU to provide power, communication and digital high speed signaling.

13. The automatic test equipment system of claim 12, wherein the plurality of hermetically-sealed flexible PCBs are configured to carry digital high speed signals enabling data rates of over 1.0 Gbps between the TIU and the ATE through at least 900 input/output (IO) channels to support scalable connections.

14. The automatic test equipment system of claim 12, wherein the hermetically-sealed flexible PCBs comprise a plurality of power cables carrying fifty ATE power planes between the ATE and the TIU.

15. The automatic test equipment system of claim 12, wherein the plurality of hermetically-sealed flexible PCBs comprise eight flexible hermetically-sealed PCBs connected within the flange assembly, each of the eight flexible hermetically-sealed PCBs comprising 113 single-ended input/output (IO) channels between the TIU and the ATE.

16. The automatic test equipment system of claim 12, wherein the vacuum-controlled passthrough environment is hermetically sealed to enable a vacuum of at least 1e⁻⁷ Torr.

17. The automatic test equipment system of claim 12, wherein the at least one flange assembly further comprises:
at least two flange assemblies, the at least two flange assemblies including:
a first flange assembly connecting a plurality of power cables and a plurality of ATE communication cables to the TIU via the aperture to the EBP; and
a second flange assembly comprising configurable hermetically sealed flexible PCBs to provide the digital high speed signaling, wherein each of the at least two flange assemblies comprise a plurality of weight bearing pins to allow the respective flange assemblies to permit mating of a plurality of hermetically-sealed PCBs to a plurality of connectors within the vacuum-controlled passthrough environment.

18. A method for an automatic test equipment system (ATE) connected to a tester in use (TIU) within a vacuum-controlled environment, the method comprising:
providing at least one flange assembly to connect the vacuum-controlled environment to an ambient environment for the ATE, the flange assembly including a vacuum-controlled passthrough environment coupled to an aperture of an electron beam probe (EBP);
connecting a plurality of ATE cables to the ATE, the plurality of ATE cables coupled to the vacuum-controlled passthrough environment of the flange assembly via at least one hermetically sealed rigid printed circuit board (PCB) having a plurality of connectors operable to separate the ambient environment from the vacuum-controlled passthrough environment; and
connecting a plurality of hermetically-sealed flexible PCBs to the plurality of connectors to transmit signals between the ambient environment and the vacuum-controlled passthrough environment.

19. The method of claim 18 further comprising:
directing, by processing circuitry within the ATE, a probe of a device under test (DUT) connected to the TIU via the EBP stimulating a portion of the DUT; and
receiving, in response, a plurality of high speed digital signals via cables coupled to the TIU via a plurality of connectors within the vacuum-controlled passthrough environment.

20. The method of claim 19, wherein the ATE cables carry scalable high speed digital signals with data rates of over 1.0 Gbps between the TIU and the ATE through 904 input/output (IO) channels to support scalable connections.
